(19) United States
(12) Patent Application Publication
(10) Pub. No.: US 2009/0294977 A1
(43) Pub. Date: Dec. 3, 2009

(54) SEMICONDUCTOR DIE AND BOND PAD ARRANGEMENT METHOD THEREOF

(76) Inventor: Che-Yuan Jao, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/351,846

(22) Filed: Jan. 11, 2009

Related U.S. Application Data
(60) Provisional application No. 61/058,200, filed on Jun. 2, 2008.

(51) Int. Cl. H01L 23/52; H01L 21/66

(52) U.S. Cl. 257/773; 438/14; 438/612; 257/E23.141; 257/E21.522

(57) ABSTRACT

A bond pad arrangement method of a semiconductor die is provided. The bond pad arrangement method includes: determining a bond pad architecture including a plurality of bond pads at a peripheral region of the semiconductor die, where each of the bond pads is defined to have a predetermined connection region; controlling an orientation of each bond pad at the peripheral region of the semiconductor die, thereby selectively configuring the predetermined connection region thereof to be electrically connected to one of a plurality of conductive structures included in at least one metal interconnect layer of the semiconductor die; and storing a bond pad design of the bond pads at the peripheral region of the semiconductor die.

### CROSS REFERENCE TO RELATED APPLICATIONS

This non-provisional application claims the benefit of U.S. provisional application No. 61/058,200, filed on Jun. 2, 2008 and included herein by reference.

### BACKGROUND

The present invention relates to bond pads of an integrated circuit (IC), and more particularly, to a semiconductor die and related bond pad arrangement method thereof.

In the semiconductor packaging field, wire bonds may be used to provide electrical connections from a semiconductor die (i.e., an integrated circuit die) to a package substrate (i.e., a substrate of a printed circuit board on which the semiconductor die is mounted). For example, wire bonds may be used to provide electrical connections between bond pads of the semiconductor die to power supply rings (e.g., power and ground rings) and bond fingers on the package substrate. Taking a ball grid array (BGA) package for example, the bond fingers on the package substrate are further coupled to solder balls located on the package surface.

However, as the semiconductor technology evolves, there is a need to increase the amount of circuitry in a single semiconductor die to provide more functions, increase the operating speed, and decrease the size of semiconductor die to make the final package more compact. An increase in the amount of the circuitry generally makes the number of electrical connections (i.e., bond wires) needed between the semiconductor die and package substrate increased, resulting in more bond pads located on the semiconductor die; however, a decrease of the size of the semiconductor die reduces amount of the space available for placing the bond pads. Thus, to meet the requirements of reducing the semiconductor die size while increasing the amount of circuitry of the semiconductor die, a need exists for a flexible and convenient bond pad design applied to the semiconductor die.

### SUMMARY

It is therefore one of the objectives of the present invention to provide a semiconductor die and related bond pad arrangement method thereof, thereby providing a flexible and convenient bond pad design.

According to one aspect of the present invention, a bond pad arrangement method of a semiconductor die is provided. The bond pad arrangement method includes: determining a bond pad architecture including a plurality of bond pads at a peripheral region of the semiconductor die, where each of the bond pads is defined to have a predetermined connection region; controlling an orientation of each bond pad at the peripheral region of the semiconductor die, thereby selectively configuring the predetermined connection region thereof to be electrically connected to one of a plurality of conductive structures included in at least one metal interconnect layer of the semiconductor die; and storing a bond pad design of the bond pads at the peripheral region of the semiconductor die.

According to another aspect of the present invention, a semiconductor die is provided. The semiconductor die includes a substrate, at least one metal interconnect layer above the substrate, and a bond pad architecture arranged at a peripheral region of the semiconductor die. The at least one metal interconnect layer is disposed above the substrate, and includes a plurality of conductive structures categorized into a first power supply network, a second power supply network, and a signal network. Each tier of the bond pad architecture has a plurality of bond pads including at least a first bond pad electrically connected to a first conductive structure and at least a second bond pad electrically connected to a second conductive structure, where the first and second conductive structures belong to different networks among the first power supply network, the second power supply network, and the signal network.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a top view of one exemplary embodiment of a semiconductor die mounted on a substrate of a printed circuit board according to the present invention.

FIG. 2 is a top view of another exemplary embodiment of a semiconductor die mounted on a substrate of a printed circuit board according to the present invention.

FIG. 3 is a top view of an exemplary embodiment of an I/O cell according to the present invention.

FIG. 4 is a sectional view along line 4′-4″ of the I/O cell shown in FIG. 3.

FIG. 5 is a top view of another exemplary embodiment of an I/O cell according to the present invention.

FIG. 6 is a top view of an exemplary embodiment of multiple I/O cells according to the present invention.

FIG. 7 is a flowchart illustrating an exemplary embodiment of a bond pad arrangement method of a semiconductor die according to the present invention.

FIG. 8 is a diagram illustrating an exemplary layout of a tri-tier bond pad architecture according to the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

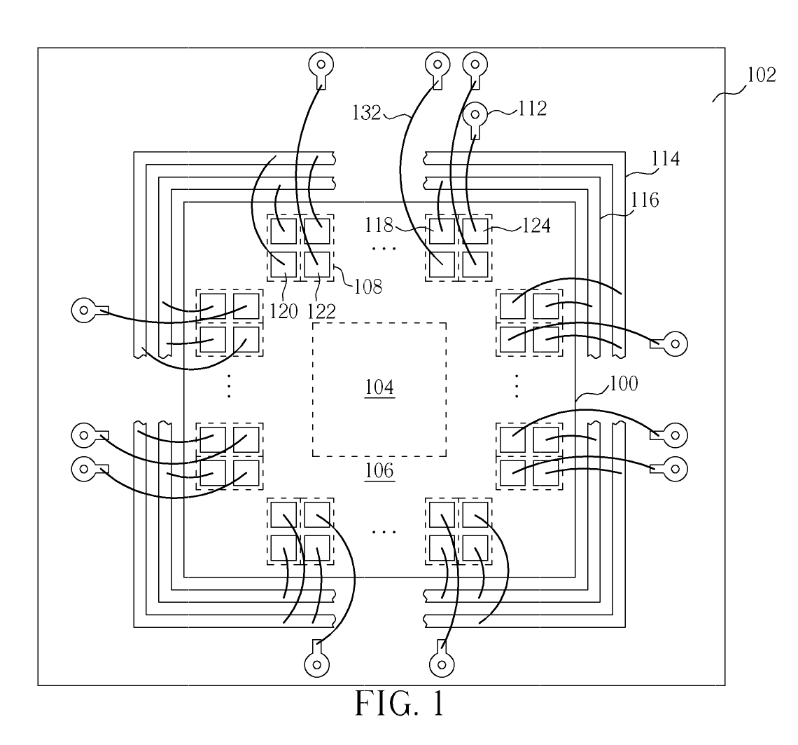

FIG. 1 is a top view of one exemplary embodiment of a semiconductor die 100 mounted on a substrate 102 of a printed circuit board (PCB) according to the present invention. The semiconductor die (i.e., an integrated circuit die) 100 includes a die core 104 and a peripheral region 106. As shown in FIG. 1, a plurality of input/output (I/O) cells 108 are arranged at the peripheral region 106 of the semiconductor die 100. The I/O cells 108 include bond pads 118, 120, 122, 124 for coupling the circuitry of the semiconductor die 100 to bond fingers 112 and power supply rings 114, 116 located on the substrate 102. The bond pads are coupled to bond fingers 112 and power supply rings 114 and 116 by bond wires 132.

In FIG. 1, the pond pads are disposed in an in-line pond pad arrangement; however, this is for illustrative purposes only. In addition, it should be noted that in some embodiments, the power supply rings 114 and 116 might be segmented to allow conductive traces to pass through the power supply rings on the die substrate. Moreover, each segment of the segmented power supply rings may be utilized to supply a different voltage potential to the die core 104 of the semiconductor die 100. In other words, the number of power supply rings shown in FIG. 1 is for illustrative purposes only. It is possible that more than two power supply rings are formed on the substrate 102 of the PCB on which the semiconductor die 100 is mounted.

In this exemplary embodiment of the present invention, the outer bond pads near the die edge are not limited to serve as power/ground bond pads only. For example, the bond pad 118 acts as a ground bond pad, while the adjacent bond pad 124 acts as a signal bond pad. Similarly, the inner bond pads behind the outer bond pads are not limited to serve as signal bond pads only. For example, the bond pad 120 acts as a power bond pad, while the adjacent bond pad 122 acts as a signal bond pad. Generally speaking, the bond pad of the present invention is defined to have a predetermined connection region, and an orientation of the bond pad can be controlled to thereby selectively configure the predetermined connection region to be electrically connected to one of a plurality of conductive structures that are routed in one or more metal interconnect layers of the semiconductor die and categorized into a first power supply network, a second power supply network, and a signal network. That is, the bond pad of the present invention therefore can be selectively configured as a power bond pad having an electrical connection with a power conductive structure (e.g., a power bus), a ground bond pad having an electrical connection with a ground conductive structure (e.g., a ground bus), or a signal bond pad having an electrical connection with a signal conductive structure (e.g., a signal conductor), depending upon the location of the predetermined connection region that is determined by the orientation of the bond pad.

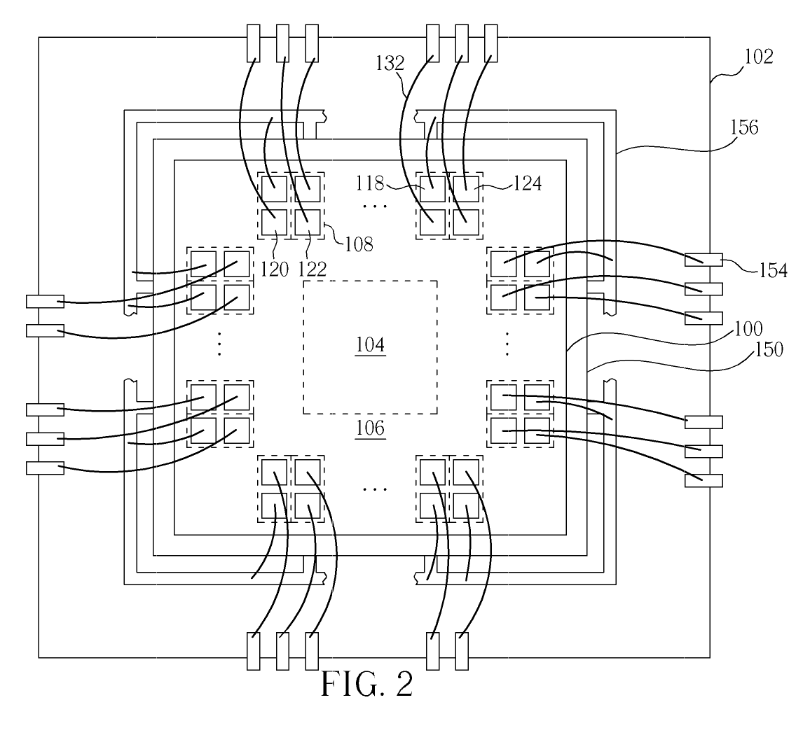

The exemplary semiconductor die 100 shown in FIG. 1 is encapsulated using a ball grid array (BGA) package. However, this merely serves as one of the exemplary embodiments of the present invention. More specifically, the bond pad arrangement of the present invention can be applied to a semiconductor die to be encapsulated using any available package techniques, including the BGA package, a quad flat package (QFP), etc. Please refer to FIG. 2, which is a top view of another exemplary embodiment of the semiconductor die 100 mounted on the substrate 102 according to the present invention. In this exemplary embodiment, the semiconductor die 100 is encapsulated using a QFP package. As shown in FIG. 2, the semiconductor die 100 is mounted on the substrate 102 through an exposed die pad (e-pad) 150 which is deliberately exposed and mounted on the substrate 102, for example, for dissipating heat generated by the semiconductor die 100. The semiconductor die (i.e., an integrated circuit die) 100 includes the die core 104 and the peripheral region 106. Besides, a plurality of input/output (I/O) cells 108 are arranged at the peripheral region 106 of the semiconductor die 100. The I/O cells 108 include bond pads 118, 120, 122, 124 for coupling the circuitry of the semiconductor die 100 to leads 154, which are located along four sides of the substrate 102 and extend outward to serve as external leads of the QFP package, and a power supply ring (i.e., a ground ring) 156, which are located on the substrate 102 and has one or more bridges connected to the die pad 150. The bond pads are coupled to leads 154 and power supply rings 156 by respective bond wires 132.

In FIG. 2, the pond pads are disposed in an in-line pond pad arrangement; however, this is for illustrative purposes only. In addition, it should be noted that in some embodiments, the power supply ring (i.e., the ground ring) 156 might be segmented such that each segment of the segmented power supply ring (i.e., the ground ring) 156 may be utilized to supply a different voltage potential to the die core 104 of the semiconductor die 100. For example, the top-right ground ring segment is configured for connecting bond pads with GND1 potential, and the bottom-right ground ring segment is configured for connecting bond pads with GND2 potential.

In this exemplary embodiment shown in FIG. 2, the ground bond pads are connected to the power supply ring (i.e., the ground ring) 156 via corresponding bond wires 132, and the power bond pads and signal bond pads are connected to the leads 154 via corresponding bond wires 132. However, the outer bond pads near the die edge are not limited to serve as power/ground bond pads only. For example, the bond pad 118 acts as a ground bond pad, while the adjacent bond pad 124 acts as a signal bond pad. Similarly, the inner bond pads behind the outer bond pads are not limited to serve as signal bond pads only. For example, the bond pad 120 acts as a power bond pad, while the adjacent bond pad 122 acts as a signal bond pad. Generally speaking, the bond pad of the semiconductor die encapsulated in the QFP package of the present invention is defined to have a predetermined connection region, and an orientation of the bond pad can be controlled to thereby selectively configure the predetermined connection region to be electrically connected to one of a plurality of conductive structures that are routed in one or more metal interconnect layers of the semiconductor die and categorized into a first power supply network, a second power supply network, and a signal network. That is, the bond pad of the semiconductor die encapsulated in the QFP package of the present invention therefore can be selectively configured as a power bond pad having an electrical connection with a power conductive structure (e.g., a power bus), a ground bond pad having an electrical connection with a ground conductive structure (e.g., a ground bus), or a signal bond pad having an electrical connection with a signal conductive structure (e.g., a signal conductor), depending upon the location of the predetermined connection region that is determined by the orientation of the bond pad.

For clear understanding of the technical features of the present invention, certain exemplary embodiments of the proposed bond pad structure employed in a semiconductor die encapsulated using any available packaging technique (e.g., a BGA package or a QFP package) are therefore detailed as follows.

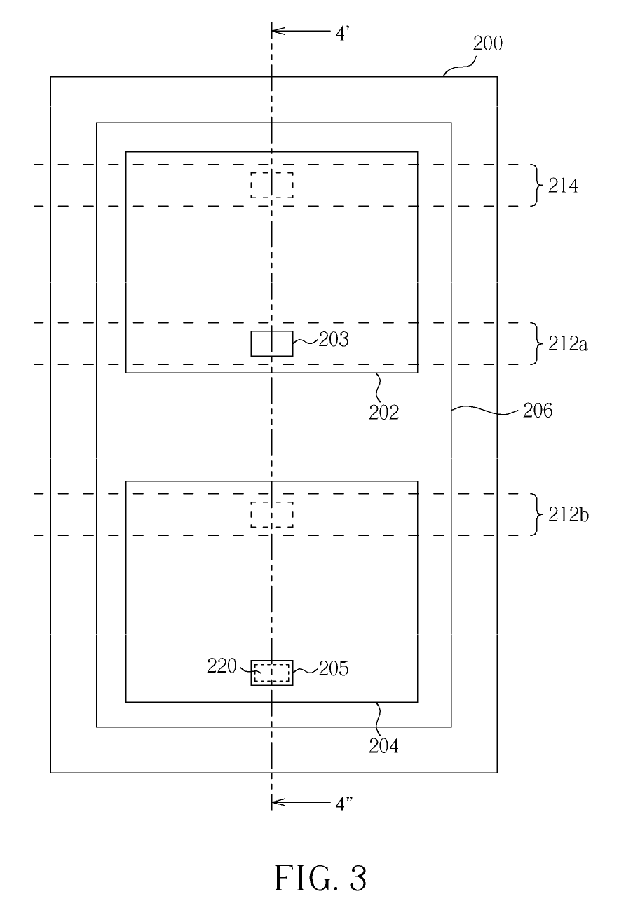

FIG. 3 is a top view of an exemplary embodiment of an I/O cell according to the present invention. The I/O cell 200 is located at the peripheral region of a semiconductor die, and includes one or more bond pads (e.g., the bond pads 202 and 204), one or more power supply buses (e.g., power buses 212a, 212b and a ground bus 214), one or more signal conductors (e.g., the signal conductor 220), and an active I/O circuitry 206. The bond pad 202 is defined to have a predetermined connection region 203, and the bond pad 204 is also defined to have a predetermined connection region 205. In this embodiment, the connection regions 203 and 205 are used to define positions where the bond pads are coupled to a metal interconnection layer. As shown in FIG. 3, when the bond pad 202 is arranged in a first orientation to make the connection region 203 placed at a lower position as shown in FIG. 3, the bond pad 202 is configured to be electrically connected to the power bus 212a; however, when the bond pad 202 is rotated from the first orientation to a second orientation which makes the connection region 203 flipped to an upper position as indicated by the broken-line box in FIG. 3, the bond pad 202 is configured to be electrically connected to the ground bus 214 instead. Similarly, when the bond pad 204 is arranged in a first orientation to make the connection region 205 placed at a lower position as shown in FIG. 3, the bond pad 204 is configured to be electrically connected to a signal conductor 220; however, when the bond pad 204 is rotated from the first orientation to a second orientation which makes the connection region 205 flipped to an upper position as indicated by the broken-line box in FIG. 3, the bond pad 204 is configured to be electrically connected to the power bus 212b instead. As one can see, the orientation of each of the bond pads 202 and 204 can be controlled according to application requirements to thereby selectively connect the corresponding connection region to one of a plurality of conductive structures (e.g., the signal conductor 220, the power buses 212a, 212b, and the ground bus 214).

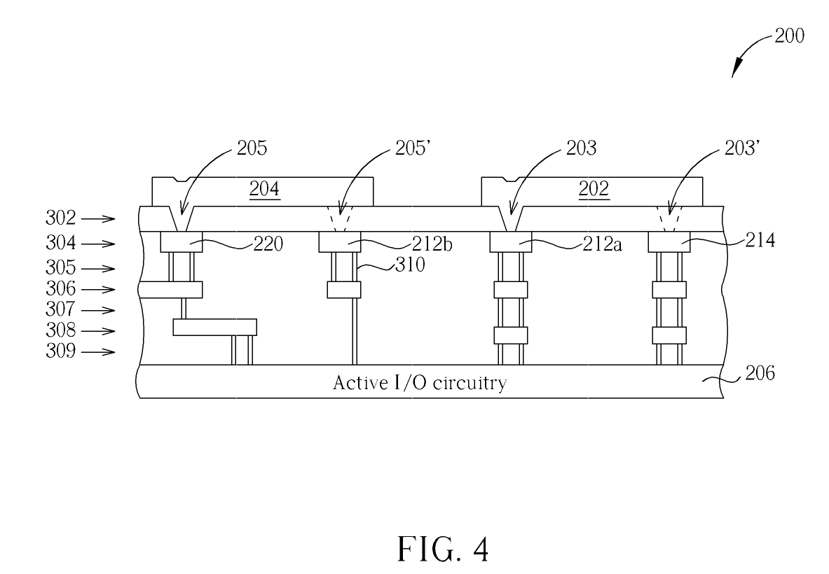

Please refer to FIG. 4. FIG. 4 is a sectional view along line 4′-4″ of the I/O cell 200 shown in FIG. 3. The bond pads 202 and 204 are shown located over a passivation layer 302. For example, the passivation layer 302 is an insulation layer made of silicon nitride. A plurality of metal interconnection layers 304, 306, and 308 and a plurality of insulation layers 305, 307, and 309 are disposed between the passivation layer 302 and a die substrate having the active I/O circuitry 206 formed therein. Please note that the number of metal interconnection layers and insulation layers shown in FIG. 4 is for illustrative purposes only. A plurality of conductive structures are formed in each of the metal interconnection layers 304, 306, and 308, and are coupled by conductive vias 310 to therefore extend through at least one intervening insulation layer 305, 307, or 309. For example, conductive structures, including the power buses 212a, 212b, the ground bus 214, and the signal conductor 220, are located in a top metal interconnection layer (i.e., the metal interconnection layer 304), and the conductive structures located in the top metal interconnection layer are electrically connected to the active I/O circuitry 206 in the die substrate through a middle interconnection layer (i.e., the interconnection layer 306), a bottom interconnection layer (i.e., the metal interconnection layer 308), and conductive vias 310. As one can see, the conductive structures are categorized into a first power supply network (e.g., power buses used for conveying power potentials), a second power supply network (e.g., ground buses used for convey ground potentials), and a signal network (e.g., signal conductors used for convey I/O signals).

As shown in FIG. 4, the bond pad 204 is located directly over the signal conductor 220 and the power bus 212b formed in the metal interconnection layer 304, and is coupled to the signal conductor 220 through an opening (via) of the passivation layer 302 at the location defined by the predetermined connection region 205. In this implementation shown in FIG. 4, the bond pad 204 is configured to be electrically connected to the signal conductor 220; however, in another implementation, the bond pad 204 is allowed to be electrically connected to the power bus 212b. For example, by rotating the bond pad 204 to make the predetermined connection region 205 placed at a flip position, as indicated by the connection region 205′ in FIG. 4, the bond pad 204 is then coupled to the power bus 212b through an opening (via) of the passivation layer 302 at the location defined by the connection region 205′.

Regarding the bond pad 202, it is located directly over the power bus 212a and the ground bus 214 formed in the metal interconnection layer 304, and is coupled to the power bus 212 through an opening (via) of the passivation layer 302 at the location defined by the predetermined connection region 203. In this implementation shown in FIG. 4, the bond pad 202 is configured to be electrically connected to the power bus 212a; however, in another implementation, the bond pad 202 is allowed to be electrically connected to the ground bus 214. For example, by rotating the bond pad 202 to make the predetermined connection region 203 placed at a flip position, as indicated by the connection region 203′ in FIG. 4, the bond pad 202 is therefore coupled to the ground bus 214 through an opening (via) of the passivation layer 302 at the location defined by the connection region 203′.

Briefly summarized, each of the bond pads of the semiconductor die according to the exemplary embodiment of the present invention can be selectively connected to a power bus, a ground bus, or a signal conductor according to design requirements of the actual application. In other words, the bond pad of the present invention is located directly over a number of conductive structures, and therefore has a plurality of connection options. For example, in a case where the bond pad is located directly over a plurality of power supply buses with different voltage potentials, such as 0V, +3.3V, −3.3V, etc, the bond pad therefore can be selectively coupled to one of the available power supply buses. In another case where the bond pad is located directly over a plurality of signal conductors configured to transmit different I/O signals, the bond pad therefore can be selectively coupled to one of the available signal conductors. In yet another case where the bond pad is located directly over one or more signal conductors and one or more power supply buses, the bond pad therefore can be selectively coupled to one of the available conductive structures to serve as a signal bond pad, a power bond pad, or a ground bond pad, depending upon design requirements.

The exemplary I/O cell 200 shown in FIG. 3 is for illustrative purposes only, and is not meant to be a limitation of the present invention. After reading above paragraphs, a person skilled in the art would readily appreciate that other configuration of an I/O cell of a semiconductor die is feasible. Certain examples of the I/O cell are given as below.

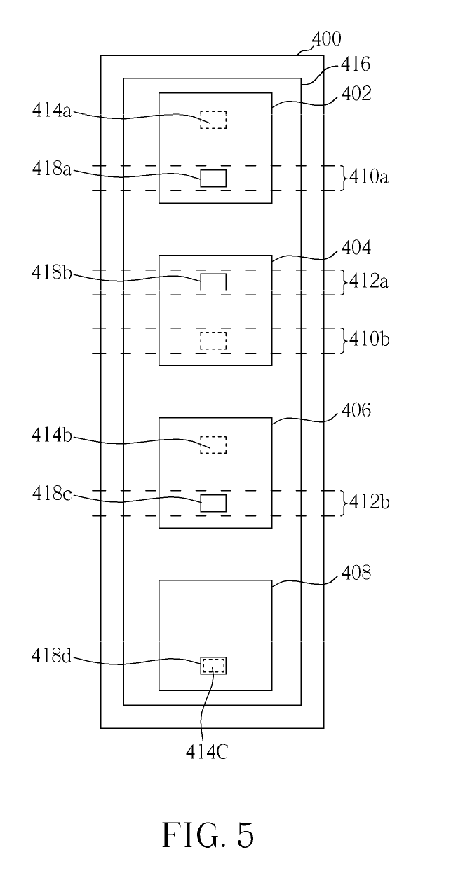

Please refer to FIG. 5. FIG. 5 is a top view of another exemplary embodiment of an I/O cell according to the present invention. The I/O cell 400 includes bond pads 402, 404, 406 and 408, power supply buses (e.g., ground buses 410a, 410b and power buses 412a, 412b, 412c), signal conductors 414a, 414b, 414c, and an active I/O circuitry 416. The bond pads 402, 404, 406, and 408 are defined to have predetermined connection regions 418a, 418b, 418c, and 418d, respectively. The bond pads 402, 404, 406, and 408 form a quad-tier bond pad architecture; in addition, the bond pads 402, 404, 406, and 408 are disposed in an in-line bond pad arrangement. An orientation of the bond pad 402 can be controlled to configure the connection region 418a to be placed at a position corresponding to the signal conductor 414a or the ground bus 410a. Similarly, an orientation of the bond pad 404 can be controlled to configure the connection region 418b to be placed at a position corresponding to the power bus 412a or the ground bus 410b; and an orientation of the bond pad 406 can be controlled to configure the connection region 418c to be placed at a position corresponding to the signal conductor 414b or the power bus 412b. In this embodiment, the bond pad 406 is only allowed to be electrically connected to the signal conductor 414c. However, in another embodiment, the bond pad 406 can be defined to have a plurality of connection options. For example, when the bond pad 406 is rotated to make the connection region 418d flipped, the bond pad 406 is therefore configured to be electrically connected to a different conductive structure such as a power bus. This also obeys the spirit of the present invention, and falls in the scope of the present invention.

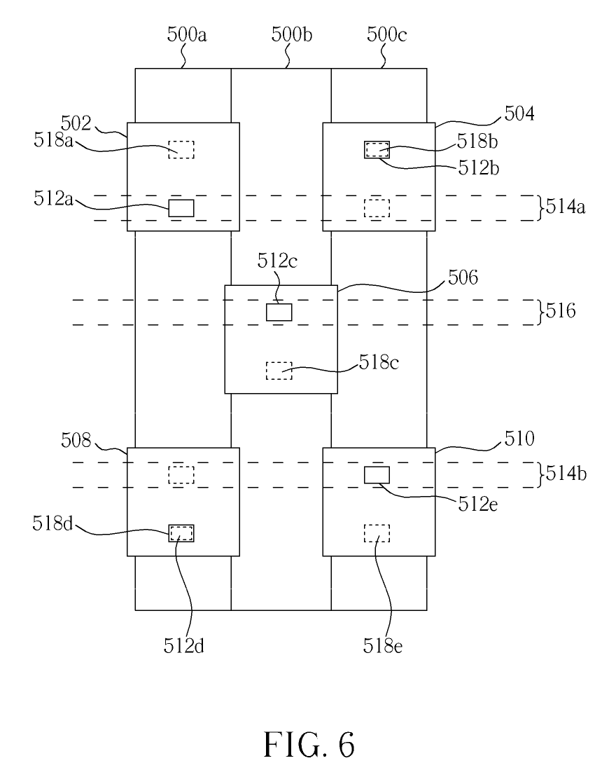

FIG. 6 is a top view of an exemplary embodiment of multiple I/O cells according to the present invention. As shown in FIG. 6, a plurality of bond pads 502, 504, 506, 508, and 510 are placed on multiple I/O cells 500a, 500b, and 500c. In addition, the bond pads 502, 504, 506, 508, and 510 form a tri-tier bond pad architecture, and are disposed in a staggered bond pad arrangement. The bond pads 502, 504, 506, 508, and 510 are defined to have predetermined connection regions 512a, 512b, 512c, 512d, and 512e, respectively. An orientation of the bond pad 502 can be controlled to configure the connection region 512a to be placed at a position corresponding to a signal conductor 518a or a ground bus 514a. Similarly, an orientation of the bond pad 504 can be controlled to configure the connection region 512b to be placed at a position corresponding to a signal conductor 518b or the ground bus 514a; an orientation of the bond pad 506 can be controlled to configure the connection region 512c to be placed at a position corresponding to a power bus 516 or a signal conductor 518c; an orientation of the bond pad 508 can be controlled to configure the connection region 512d to be placed at a position corresponding to a signal conductor 518d or a ground bus 514b; and an orientation of the bond pad 510 can be controlled to configure the connection region 512e to be placed at a position corresponding to the ground bus 514b or a signal conductor 518e.

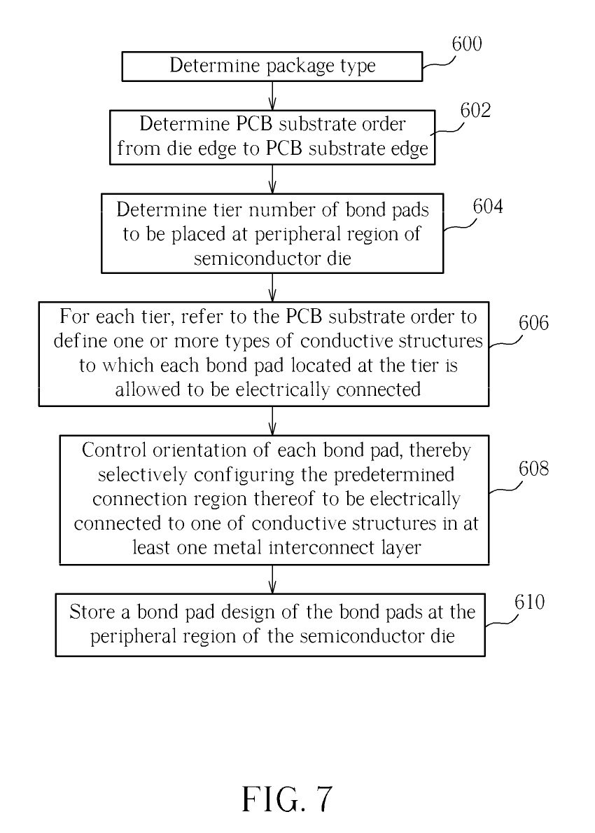

Please refer to FIG. 7. FIG. 7 is a flowchart illustrating an exemplary embodiment of a bond pad arrangement method of a semiconductor die according to the present invention. Please note that if the result is substantially the same, the steps are not limited to be executed in the exact order shown in FIG. 7. The flow of the bond pad arrangement method includes following steps:

Step 600: Determine a package type of a semiconductor package employed to encapsulate a semiconductor die.

Step 602: Determine an order of power supply conductors and signal conductors (e.g., power ring(s), ground ring(s), and bond fingers for BGA packaging, or ground ring(s) and leads for QFP packaging) formed on a substrate of a printed circuit board (PCB) on which the semiconductor die is to be mounted and between an edge position of the semiconductor die (i.e., the die edge) and an edge position of the PCB (i.e., an edge of the package substrate).

Step 604: Determine a tier number of bond pads to be placed at a peripheral region of the semiconductor die.

Step 606: For each tier, refer to the order of power supply conductors and signal conductors on the substrate of the PCB to define one or more types of conductive structures to which each bond pad located at the tier is allowed to be electrically connected. Preferably, each bond pad defined in a peripheral region of a semiconductor die is allowed to have multiple connection options, thereby providing optimum flexibility of a bond pad design for an objective application.

Step 608: Control an orientation of each bond pad at the peripheral region of the semiconductor die, thereby selectively configuring the predetermined connection region thereof to be electrically connected to one of a plurality of conductive structures routed in at least one metal interconnect layer of the semiconductor die.

Step 610: Store a bond pad design of the bond pads at the peripheral region of the semiconductor die.

The bond pad arrangement method of the present invention can be applied to a semiconductor die to be encapsulated using any available package techniques, such as a ball grid array (BGA) package or a quad flat package (QFP). That is, any package which encapsulates a semiconductor die employing the afore-mentioned bond pad arrangement technique obeys the spirit of the present invention, and falls within the scope of the present invention. After the package type is chosen (step 600), the PCB substrate order from the die edge to the PCB substrate edge (i.e., the package substrate edge) is then determined (step 602). Specifically, an order of power supply conductors and signal conductors (e.g., power ring(s), ground ring(s) and bond fingers for BGA packaging, or ground ring(s) and leads for QFP packaging) formed on a PCB substrate on which the semiconductor die is to be mounted is determined in step 602. Taking the substrate 102 shown in FIG. 1 for example, the PCB substrate order from the die edge to the PCB substrate edge is the ground ring 116, the power ring 114, and then the bond fingers 112.

Next, with regard to the BGA packaging, step 604 determines the active I/O circuitry bond pad number according to the power rings to which the power bond pads are connected, ground rings to which the ground bond pads are connected, and bond fingers to which the signal bond pads are connected; similarly, with regard to the QFP packaging, step 604 determines the active I/O circuitry bond pad number according to the ground rings to which the ground bond pads are connected and the leads to which the power bond pads and signal bond pads are connected. For example, a multi-tier bond pad architecture (e.g., a quad-tier or tri-tier bond pad architecture) that can satisfy the bonding requirements is adopted for the BGA or QFP packaging. For each tier, the bond pad arrangement method refers to the PCB substrate order determined in step 602 to define one or more types of conductive structures, including a power bus, a ground bus, and a signal conductor, to which each bond pad located at the tier is allowed to be electrically connected (step 606). For example, regarding an exemplary quad-tier bond pad architecture having the 1^{st} tier near the die edge, and the 2^{nd} tier, the 3^{rd} tier, and 4^{th} tier successively behind the 1^{st} tier (i.e., the 1^{st} tier is the outer-most tier, while the 4^{th} tier is the inner-most tier), each bond pad located at the 1^{st} tier is allowed to be selectively coupled to a signal conductor for serving as a signal bond pad or a ground bus for serving as a ground bond pad (e.g., a VSS or GND bond pad); each bond pad located at the 2^{nd} tier is allowed to be selectively coupled to a power bus for serving as a power bond pad (e.g., a VCC or VDD bond pad) or a ground bus for serving as a ground bond pad (e.g., a VSS or GND bond pad); each bond pad located at the 3^{rd} tier is allowed to be selectively coupled to a signal conductor for serving as a signal bond pad or a power bus for serving as a power bond pad (e.g., a VCC or VDD pond pad); and each bond pad located at the 4^{th} tier is allowed to be coupled to a signal conductor for serving as a signal bond pad.

A bond pad architecture including a plurality of bond pads at a peripheral region of the semiconductor die is defined according to steps 604 and 606, where each of the bond pads is defined to have a predetermined connection region that can be selectively coupled to one of permissible conductive structures. In the following step 608, an orientation of each bond pad at the peripheral region of the semiconductor die is controlled to thereby selectively configure the predetermined connection region thereof to be electrically connected to one of a plurality of conductive structures. In the end, a bond pad design of the bond pads at the peripheral region of the semiconductor die is stored (step 610).

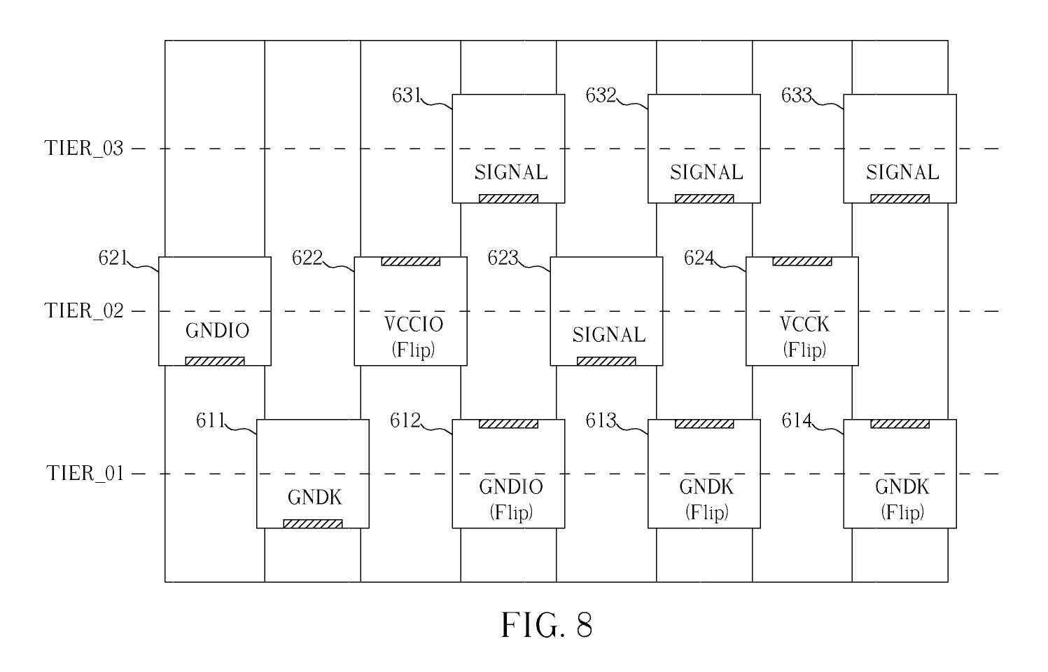

Please refer to FIG. 8. FIG. 8 is a diagram illustrating an exemplary layout of a tri-tier bond pad architecture according to the present invention. The tri-tier bond pad architecture includes a plurality of bond pads at different tiers TIER_01 , TIER_02, and TIER_03. In this exemplary embodiment, each bond pad located at the first tier TIER_01 is allowed to be coupled to a signal conductor when the bond pad is not flipped or coupled to a ground bus when the bond pad is flipped; each bond pad located at the second tier TIER_02 is allowed to be coupled to a signal conductor when the bond pad is not flipped or coupled to a power bus when the bond pad is flipped; and each bond pad located at the third tier TIER_03 is allowed to be coupled to a signal conductor only. However, it should be noted that in an alternative design, each bond pad located at the third tier TIER_03 can be designed to be selectively coupled to one of a plurality of conductive structures. This also obeys the spirit of the present invention, and falls within the scope of the present invention.

The bond pads shown in FIG. 8 have aforementioned connection regions illustrated by shaded areas in FIG. 8, and correspond to many I/O types such as VCCIO type, VCCK type, GNDIO type, GNDK type, and SIGNAL type. As the bond pad 611 of the GNDK type is not flipped, the connection region of the bond pad 611 is placed at a lower position, and the bond pad 611 is therefore configured to be electrically connected to a signal conductor. Regarding the bond pads 613 and 614 having the same GNDK type, they are flipped to place the corresponding connection regions at upper positions, and are configured to be electrically connected to a ground bus with a second voltage potential GND2. Regarding the bond pad 612 having the GNDIO type, it is flipped to place the connection region at an upper position, and is therefore configured to be electrically connected to a ground bus with a first voltage potential GND1. Though each bond pad located at the first tier TIER_01 is defined to be coupled to a ground bus when the bond pad is flipped, the bond pads 613, 614 and the bond pad 612 are connected to different voltage potentials due to different I/O types. Similarly, though each bond pad located at the second tier TIER_02 is defined to be coupled to a power bus when the bond pad is flipped, the bond pad 622 and the bond pad 624 are respectively connected to different voltage potentials PWR1 and PWR2 due to different I/O types.

In conclusion, the bond pad arrangement method of a semiconductor die according to the present invention includes: defining a bond pad architecture including a plurality of bond pads at a peripheral region of the semiconductor die, where each of the bond pads is defined to have a predetermined connection region; and controlling an orientation of each bond pad, thereby selectively configuring the predetermined connection region thereof to be electrically connected to one of a plurality of conductive structures included in metal interconnect layer(s), where the conductive structures are generally categorized into a first power supply network (i.e., power buses), a second power supply network (i.e., ground buses), and a signal network (i.e., signal conductors). In this way, a flexible and convenient bond pad design method is provided.

One exemplary implementation of a semiconductor die configured using the above-mentioned bond pad arrangement method (e.g., the semiconductor die 100 shown in FIG. 1 and FIG. 2) therefore includes a substrate, at least one metal interconnect layer disposed above the substrate and including a plurality of conductive structures categorized into a first power supply network, a second power supply network, and a signal network, and a bond pad architecture arranged at a peripheral region of the semiconductor die. Each tier of the bond pad architecture has a plurality of bond pads including at least a first bond pad electrically connected to a first conductive structure and at least a second bond pad electrically connected to a second conductive structure. The first and second conductive structures belong to different networks among the first power supply network, the second power supply network, and the signal network.

In addition, in a case where the orientation of each bond pad is finalized prior to the actual layout design of conductive traces routed at a top metal interconnection layer (e.g., the metal interconnection layer 304 shown in FIG. 4), a designer therefore can properly change the routing of power buses, ground buses, and signal conductors to make them successfully connected to corresponding bond pads through openings (vias) formed in the passivation layer.

In general, each bond pad of the present invention with multiple connection options is a square bond pad. Therefore, the connection of the bond pad can be easily configured by rotating or flipping the square bond pad to change the position of the predetermined connection region defined on the bond pad. For example, in one case where the square bond pad is allowed to have two connection options, the square bond pad may be flipped to make the predetermined connection region thereof placed at a location corresponding to a desired conductive structure. However, in another case where the square bond pad is allowed to have more than two connection options, the square bond pad may be rotated clockwise or anticlockwise to make the predetermined connection region placed at a location corresponding to a desired conductive structure. For instance, the square bond pad has four connection options, and each 90-degree rotation will make the predetermined connection region placed at a different location corresponding to one of four conductive structures. Please note that in above exemplary embodiments, the bond pads shown in the drawings are similar in size; however, this is not meant to be a limitation of the present invention. In other embodiments, the bond pads may be of different sizes.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A bond pad arrangement method of a semiconductor die, comprising:
determining a bond pad architecture including a plurality of bond pads at a peripheral region of the semiconductor die, wherein each of the bond pads is defined to have a predetermined connection region;
controlling an orientation of each bond pad at the peripheral region of the semiconductor die, thereby selectively configuring the predetermined connection region thereof to be electrically connected to one of a plurality of conductive structures included in at least one metal interconnect layer of the semiconductor die; and
storing a bond pad design of the bond pads at the peripheral region of the semiconductor die.

2. The bond pad arrangement method of claim 1, further comprising:
determining an order of power supply conductors and signal conductors between an edge position of the semiconductor die and an edge position of a printed circuit board (PCB) on which the semiconductor die is to be mounted;
wherein the power supply conductors and the signal conductors are formed on the PCB; and the bond pad architecture is defined according to the order of the power supply conductors and the signal conductors.

3. The bond pad arrangement method of claim 1, wherein the step of defining the bond pad architecture comprises:
determining a tier number of bond pads to be placed at the peripheral region of the semiconductor die; and
for each tier, defining one or more types of conductive structures to which each bond pad located at the tier is allowed to be electrically connected.

4. The bond pad arrangement method of claim 1, wherein the step of controlling the orientation of each bond pad comprises:
rotating the bond pad to make the predetermined connection region placed at a specific position, thereby configuring the predetermined connection region to be electrically connected to a specific conductive structure corresponding to the specific position.

5. A semiconductor die, comprising:
a substrate;
at least one metal interconnect layer positioned above the substrate, wherein the at least one metal interconnect layer includes a plurality of conductive structures categorized into a first power supply network, a second power supply network, and a signal network; and
a bond pad architecture, arranged at a peripheral region of the semiconductor die, each tier of the bond pad architecture comprising:
a plurality of bond pads, including at least a first bond pad electrically connected to a first conductive structure, and at least a second bond pad electrically connected to a second conductive structure, wherein the first and second conductive structures belong to different networks among the first power supply network, the second power supply network, and the signal network.

6. The semiconductor die of claim 5, wherein the pad architecture is a multi-tier bond pad architecture.

7. The semiconductor die of claim 5, wherein the bond pads are disposed in an in-line bond pad arrangement.

8. The semiconductor die of claim 5, wherein the bond pads are disposed in a staggered bond pad arrangement.
